(19) United States
(12) Patent Application Publication
(10) Pub. No.: US 2008/0080257 A1
(43) Pub. Date: Apr. 3, 2008

(54) Flash memory device and its reading method

(75) Inventors: Jin Su Park, Daegu (KR); Gi Hyun Bae, Kyeongki-do (KR); Joong Seob Yang, Kyeongki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc.

(21) Appl. No.: 11/645,763

(22) Filed: Dec. 27, 2006

(30) Foreign Application Priority Data
Sep. 29, 2006 (KR) 2006-96215

(51) Int. Cl. G11C 16/04; G11C 11/34; G11C 14/00

(52) U.S. Cl. 365/185.33; 365/185.08

(57) ABSTRACT

The present invention relates to a flash memory device and a reading method thereof wherein, in a page buffer of a flash memory device, a transmitting unit is disposed between a bit line and a sensing node and the lengths of the sensing node wiring are configured to be the identical across all page buffers. In addition, the wirings of a plurality of sensing nodes are disposed on separate levels, low and high, so as to not to be adjacent to each other, such that the loading time of the sensing nodes of the page buffers are uniform and the coupling capacitance between the sensing node wirings is excluded, thereby resulting in an accurate reading operation of data.

### CROSS-REFERENCE TO RELATED APPLICATIONS

The present application claims priority to Korean patent application number 10-2006-096215, filed on Sep. 29, 2006, which is incorporated by reference in its entirety.

### BACKGROUND OF THE INVENTION

The present invention relates to a flash memory device and its reading method, and more particularly, to a flash memory device and its reading method that are not affected by interference between sensing-node wirings of the page buffer.

Recently, there has been an increased need for semiconductor memory devices in which it is possible to electrically program and erase, and which does not need to be periodically refreshed. In addition, research and development has been vigorously performed on highlg integrating a memory device in order to fabricate a memory device with a large data capacity. Here, “to program” refers to writing data on a memory cell and “to erase” refers to erasing the data written on the memory cell.

Meanwhile, a NAND-type flash memory device in which a plurality of memory cells are serially connected to highly integrate the memory device (that is, a configuration in which cells adjacent to each other co-occupy a drain region or a source region) in such a way as to form a string was developed. The NAND-type flash memory device, as opposed to a NOR-type flash memory device, is a memory device that reads subsequent information. Programming and erasing the NAND-type flash memory is performed in such a way as to inject electrons into a floating gate and discharge them therefrom for controlling a threshold voltage of the memory cell by using a F-N tunneling method.

In addition, a page buffer is used in the NAND-type flash memory device to store a large amount of information in a short time period.

FIG. 1 is circuit of a memory device showing a page buffer of a memory device according to a conventional art.

Referring to FIG. 1, the page buffer (for example; PB[0]) includes a bit line selection unit 10 which connects a sensing node SO[0] alternatively to an even bit line BLe[0] or an odd bit line Blo[0], and a sensing unit 20 which senses the data on the bit line BLe[0] or BLo[0] which is selected by the sensing unit 20. The page buffer, as configured in the aforementioned manner, is connected to a plurality of pair of bit lines BLe and BLo. The bit line selection unit is fabricated as a high voltage transistor to share a same well such that in the erase operation it can endure the high voltage applied to the bit line BLe[0] or BLo[0].

FIG. 2 is a waveform view showing a read operation of the flash memory page buffer as configured in FIG. 1.

A reset signal is applied to an NMOS transistor N8 of sensing unit 20 to reset QA[0] to a low level. In addition, discharge switches DISCHe, DISCHo are applied to NMOS transistors N1 and N2 of the bit line selection unit 10 at a high level. Accordingly, the NMOS transistors N1, N2 are turned on to apply a bias voltage VIRPWR to the bit lines BLe[0], BLo[0]. At this time, the bias voltage VIRPWR is 0V and thus the bit lines BLe[0], BLo[0] are discharged to become 0V.

Meanwhile, a pre-charge signal PRECHb at a low level is applied to a PMOS signal of the sensing unit 20 to pre-charge the sensing node SO[1] to a high level. For example, if the even bit line BLe[0] is selected, the discharge signal DISCHe is transited to a low level to turn on the NMOS transistor N1 of the bit line selection unit 10. In addition, a bit line selection signal BSLe at the V1 level is applied to the NMOS transistor N3 of the bit line selection unit 10 for a predetermined time period. Therefore, the even bit line BLe[0] has the voltage of V1 minus the threshold voltage Vt, or V1−Vt. At this time, the odd bit line BLo[0] remains at 0V.

In addition, the pre-charge signal PRECHb is transited to a high level to turn off a PMOS transistor P1. Then, a bit line selection signal BSLe of a V2 level is applied to an NMOS transistor N3 of the bit line selection unit 10. At this time, if the voltage of the even bit line BLe[0] is equal or greater than V2−Vt, the NMOS transistor N3 remains in the turn off state and thus a sensing node SO[0] remains at a high level. In contrast, if the voltage of the even bit line BLe[0] is equal or less than V2−Vt, the NMOS transistor N3 is turned on to share charges between the sensing node SO[0] and the bit line BLe[0]. Then, a reading signal READ at a high level is applied to the NMOS transistor N7 of the sensing unit 20 to drive the NMOS transistor N6 with the voltage of the sensing node SO[0]. Accordingly, data is stored on the latch consisting of IV2, IV3 depending on the voltage of the sensing node SO[0].

The page buffer according to the aforementioned conventional art is configured such that the wiring length of the sensing node 20 is different from the wiring length of sensor nodes in other page buffers depending on a disposition configuration thereof since one page buffer is difficult to dispose between pitches of two bit lines and thus one page buffer is connected to two bit lines (the even and odd bit lines). As a result, the wiring lengths of the sensing nodes of the plurality of page buffers are different from each other and thus loading times and capacitances thereof are different from each other.

FIG. 3 is a graph showing charge sharing of a sensing node voltage depending on the wiring length of the sensing node.

Referring to FIG. 3, the capacitances depending on the wiring lengths of the sensing node 20 are different and thus the time periods for the lowering of the voltage levels are different from each other. That is, to lower the voltages of each of the sensing nodes to a predetermined level during a same time period, lower bit voltages are required when the sensing node has less capacitance, due to the greater capacitance of the wiring of the sending node. Therefore, the cell currents sensed by the page buffers are different from each other depending on the capacitances of the wirings of the sending node.

FIG. 4 is a graph showing a reading margin of the page buffer according to the conventional art.

The cell currents sensed by a page buffer are different depending on dispositions of the wirings of the sensing node. Accordingly, the cell current sensed by the page buffer that has the worst loading of the sensing node shall be greater than the leak current flowing on the bit lines. This difference becomes a “0” cell margin. In contrast, the cell current sensed by the page buffer that has the best loading of the sensing node shall be worse than the worst on-cell current among on-cell currents. This difference becomes a “1” cell margin. The differences of the currents sensed by the page buffers disposed differently mean a decrease of the reading margin gap.

In addition, the gap between the sensing nodes SO[0] and SO[1] of the adjacent page buffers PB[0] and PB[1] becomes narrow such that a coupling capacitance Cso is enlarged and a drop of the voltage of the sensing node may be produced, and it may accordingly cause a failure in sensing ‘1’ data by an error of the page buffer if a memory cell data is ‘0’ in a reading operation.

### SUMMARY OF THE INVENTION

The technical subject of the present invention is to provide a flash memory device and a reading method thereof wherein, in a page buffer of a flash memory device, a transmitting unit is disposed between a bit line and a sensing node and the lengths of the respective sensing node wiring are configured to be the same. In addition, the wirings of a plurality of sensing nodes are disposed on the separate low level and high level not to be adjacent such that the loading time periods of the sensing node of the page buffer is the same and a coupling capacitance between the sensing node wirings is avoided, thereby resulting in accurate reading operations.

A flash memory device according to one aspect of the present invention includes a plurality of memory cell, wherein the plurality of memory cell comprises a plurality of memory cell arrays that are connected to a plurality of pairs of bit lines; and a plurality of page buffers to read the data on the selected memory cell among the plurality of memory cells, which is connected to the respective pair of bit lines, wherein each of the plurality of page buffers includes: a bit line selection unit that selects one bit line among the pair of bit lines and connects it to a sharing node; a transmitting unit that connects the bit line selection unit to the sensing node; and a sensing unit that stores the data on the memory cell selected, transmitted through the sensing node, wherein the bit line selection unit is disposed on a high voltage region of a memory device, and the transmitting unit and sensing unit are disposed on a low voltage region of the device.

In addition, each of the plurality page buffers includes: a bit line selection unit that selects one bit line among the pair of bit lines and connects it to a sharing node; a transmitting unit that connects the bit line selection unit to the sensing node; and a sensing unit that stores the data on the memory cell selected, transmitted through the sensing node, wherein the bit line selection unit is disposed on a high voltage region of a memory device, and the transmitting unit and sensing unit are disposed on a low voltage region of the device.

A reading method for a flash memory device includes the steps of connecting the selection bit lines to which the selected memory cells among the plurality of memory cells are connected, to the respective sharing node of the plurality of page buffers; pre-charging the sharing node to a high level and then transmitting the data on the selected memory cell from the sharing node to the sensing node; and storing the data on the selected memory cell, which is transmitted to the sensing node, on the page buffer.

### BRIEF DESCRIPTION OF THE DRAWINGS

The following drawings, which are included to provide a further understanding of the invention and are incorporated in and constitute a part of this specification, illustrate embodiments of the invention and together with the description serve to explain the principle of the invention. In the drawings:

FIG. 1 is circuit of a memory device to show a page buffer of the memory device according to a conventional art.

FIG. 2 is a waveform view showing a reading operation of the page buffer on the flash memory device as configured in FIG. 1.

FIG. 3 is a graph showing a charge sharing of a sensing node voltage depending on the wiring length of the sensing node.

FIG. 4 is a graph showing a reading margin of the page buffer according to the conventional art.

FIG. 5 is a view showing a configuration of a flash memory device according to one embodiment of the present invention;

FIG. 6 is a view showing a detailed circuit of the page buffer as shown in FIG. 5;

FIG. 7 is a waveform view of signals showing a reading method of the flash memory device by using the page buffer as shown in FIG. 6;

FIG. 8 is a concept view showing an operation of a charge sharing in the reading operation according to the present invention; and

FIG. 9 is a graph showing a reading margin in the reading operation according to the present invention.

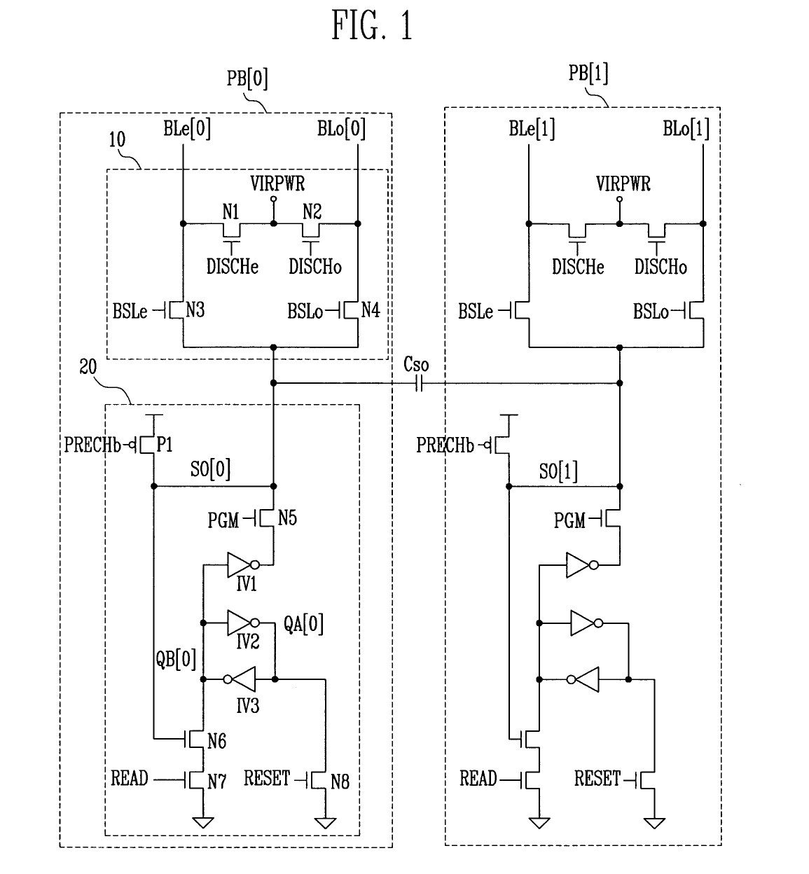

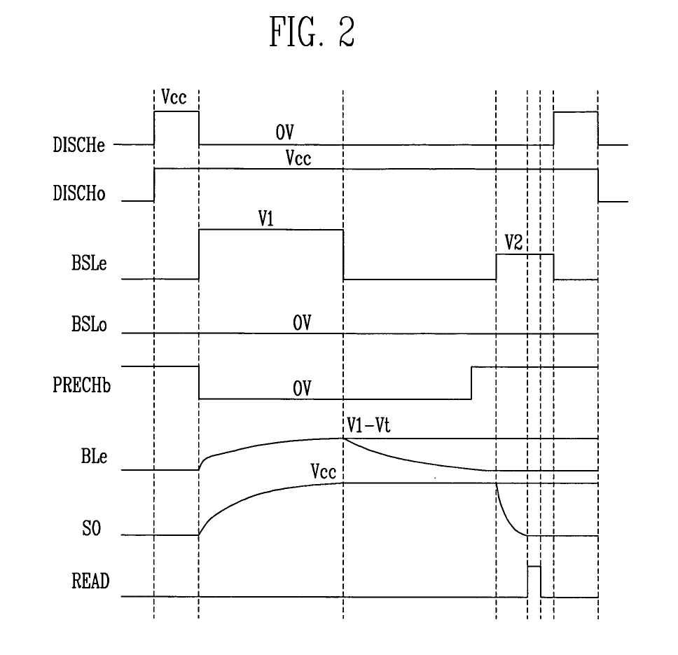

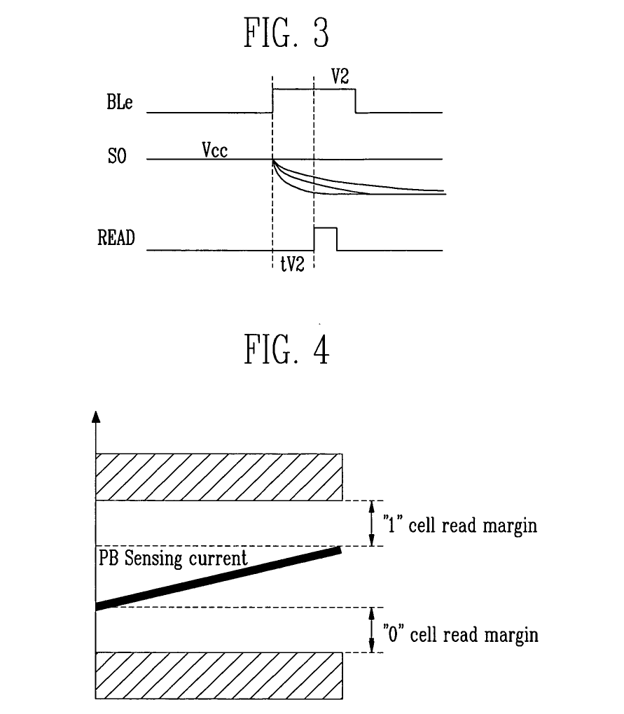

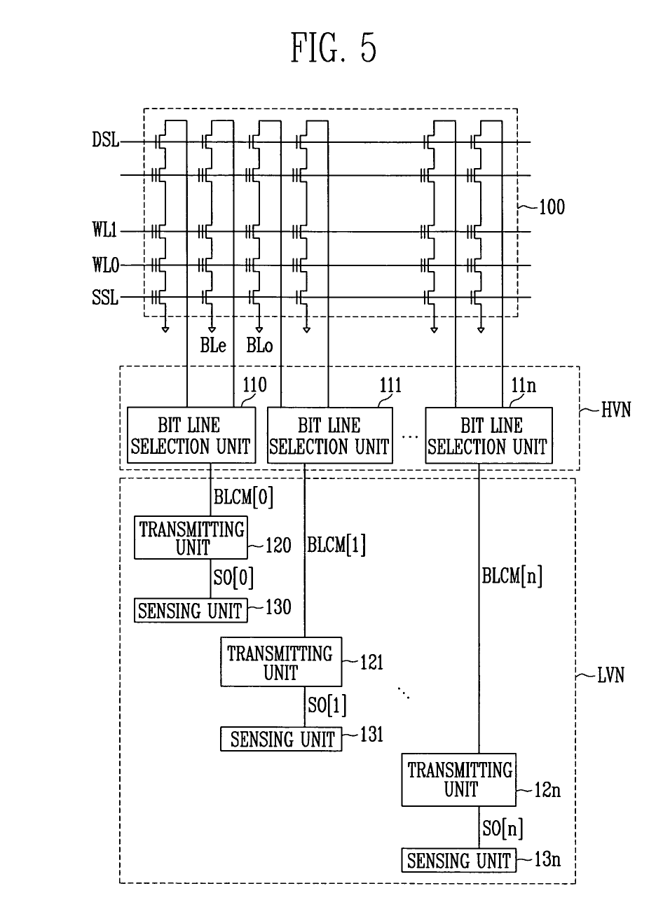

### DESCRIPTION OF SPECIFIC EMBODIMNETS

Following, the preferred embodiments of the present invention will be described in conjunction with the accompanying drawings. However, it is to be understood that both the foregoing general description and the following detailed description are exemplary and explanatory and are intended to provide further explanation of the invention as claimed.

FIG. 5 is a view showing a configuration of a flash memory device according to one embodiment of the present invention.

Referring to FIG. 5, a flash memory device includes a memory cell array 100, a plurality of bit line selection units 110 to 11n, where n is an integer; a plurality of transmitting units 120 to 12n, where n is an integer; and a plurality of sending unit 130 to 13n, where n is an integer.

The memory cell array 100 includes a plurality of memory cells and the plurality of memory cells are connected as a string structure to form a plurality of bit lines BLe and BLo. Each of a plurality of bit line selection units 110 to 11n is connected to pair of bit lines BLe and BLo and connects one bit line of the pair of bit lines BLe and BLo to a sharing line (for example; BLCM[0]). Each of the plurality of transmitting units 120 to 12n is connected between the sharing lines BLCM[0] to BLCM[n] and sensing nodes SO[0] to SO[n], respectively, such that it connects the sharing lines BLCM[0] to BLCM[n] to the sensing nodes SO[0] to SO[n]. Each of the plurality of sensing units 130 to 13n is connected to the sensing nodes SO[0] to SO[n], respectively, and senses and stores the data transmitted to the sensing nodes SO[0] to SO[n]. The plurality of bit line selection units 110 to 11n are formed on a high voltage transistor region HVN, and the plurality of transmitting units 120 to 12n and plurality of sensing units 130 to 13n are formed on a low voltage region LVN.

Meanwhile, a page buffer includes one bit line selection unit (for example; 110) connected to one pair of bit lines BLe and BLo, one transmitting unit (for example; 120), and one sending unit (for example; 130). The plurality of sensing nodes SO[0] to SO[n] are disposed at the same length on the low voltage region LVN. Here, the sensing nodes are formed not to be adjacent to each other and disposed on different levels (for example; upper level and lower level) depending on the disposition of the sensing units 130 to 13n. As a result, the coupling capacitances between the sensing nodes SO[0] to SO[n] do not exist.

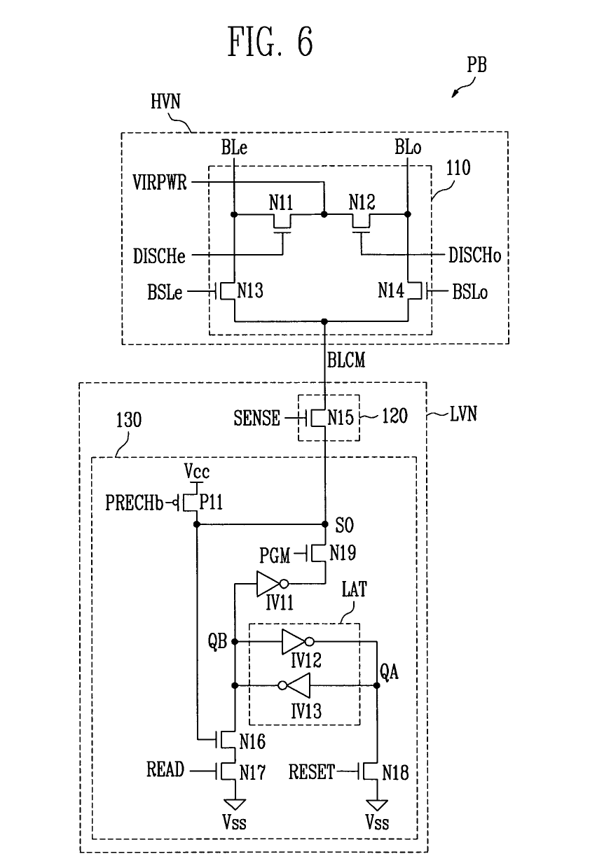

FIG. 6 is a view showing a detailed circuit of the page buffer as shown in FIG. 5.

Referring to FIG. 6, a page buffer PB includes a bit line selection unit 110, a transmitting unit 120 and a sensing unit 120.

The bit line selection unit 110 includes a plurality of NMOS transistors N11 to N14. The NMOS transistor N11 is connected between the bit line BLe and bias voltage VIRPWR and applies the bias voltage VIRPWR to the bit line BLe in response to a discharge signal DISCHe. The NMOS transistor N12 is connected between the bit line BLo and bias voltage VIRPWR and applies the bias voltage VIRPWR to the bit line BLo in response to a discharge signal DISCHo. The NMOS transistor N13 is connected between the bit line BLe and sharing line BLCM and connects the bit line BLe to the sharing line BLCM in response to the bit line selection signal BSLe. The NMOS transistor N14 is connected between the bit line BLo and sharing line BLCM and connects the bit line BLo to the sharing line BLCM in response to the bit line selection signal BSLe.

The transmitting unit 120 is connected between the sharing line BLCM and sensing node SO and connects the sharing line BLCM to the sensing node SO in response to the sensing signal SENSE.

The sensing unit 130 includes a PMOS transistor P11, a plurality of NMOS transistor N16 to N19, a latch LAT, and an inverter IV11. The PMOS transistor P11 is connected between a source voltage and the sensing node SO and connects the source voltage to the sensing node SO in response to the pre-charge signal PRECHb. The latch LAT includes the inverters IV12 and IV13 that are connected in parallel in a reverse direction between nodes QA and QB. The NMOS transistors N16 and N17 are serially connected between the node QA and ground power source Vss and are driven in response to a voltage of the sensing node SO and the reading signal READ, respectively. The NMOS transistors N16 and N17 are turned on simultaneously to connect the node QB to a ground power source. The NMOS transistor N18 is connected between the node QA and ground power source and connects the node QA to the ground power source responding to the reset signal RESET. The inverter IV11 is connected to the node QA and outputs the reversed signal of the node QA. The NMOS transistor N19 is connected between the output end of the inverter IV11 and the sensing node SO and transmits the output signals of the inverter IV11 to the sensing node SO, responding to a program signal PGM.

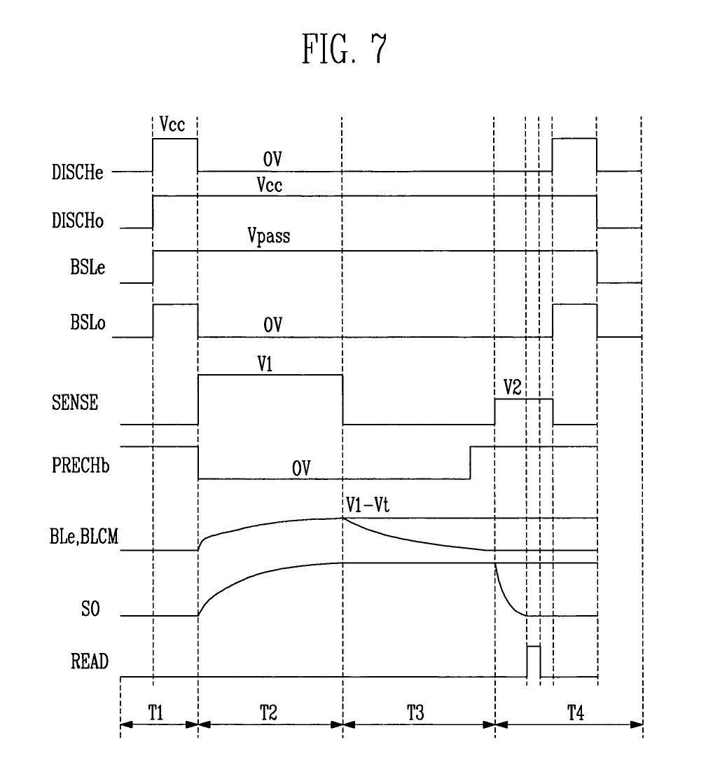

FIG. 7 is a waveform view of signals showing a reading method of the flash memory device by using the page buffer as shown in FIG. 6.

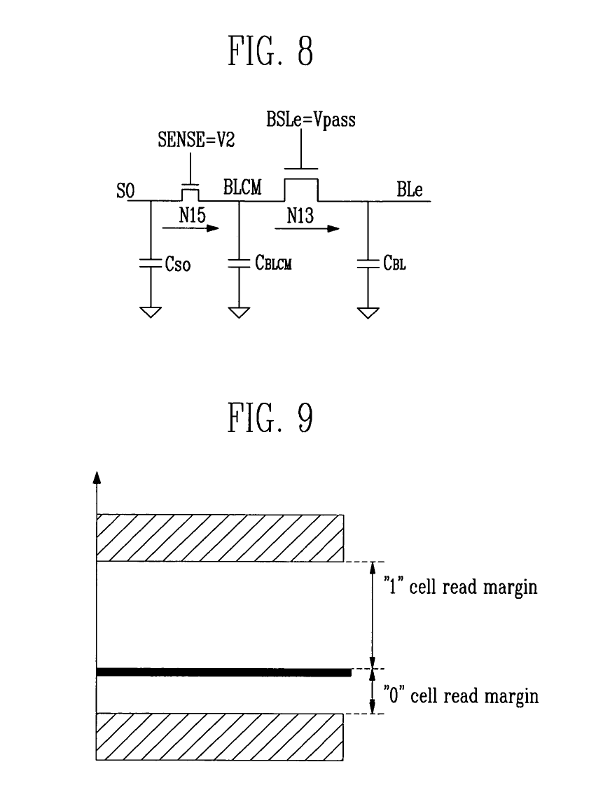

FIG. 8 is a concept view showing an operation of a charge sharing in the reading operation according to the present invention.

Referring to FIGS. 5 to 9, a detailed description of a read operation in a flash memory according to the present invention will be described as follows. Here, the description will be given to a method of reading data on the even bit line BLe as one embodiment of the present invention.

In the first step (T1), the reset signal RESET is transited to a high level for a predetermined time period to turn on the NMOS transistor N18. Accordingly, the node QA is connected to the ground power source and discharge to a low level to reset the node QA

The discharge signals DISCHe and DISCHo of low levels are transited to a high level to turn on the NMOS transistors N11 and N12. Therefore, the bias voltage VIRPWR is applied to the bit lines BLe and BLo. At this time, the bias voltage VIRPWR becomes 0V.

The bit line selection signals BSLe and BSLo at high levels are applied to the NMOS transistors N13 and N14 to connect the bit lines BLe and BLo to the sharing node BLCM.

In the second step (T2), the discharge signal DISCHe to be applied at a high level, is transited to low level to turn off the NMOS transistor N11, and thus cut off the bias voltage VIRPWR from the bit line BLe.

The bit line selection signal BSLo at a high level is transited to a low level and cuts off the connection between the bit line BLo and sharing node BLCM, and thus only the bit line BLe and sharing node BLCM are connected.

The pre-charge signal PRECHb at a high level is transited to a low level to turn on the NMOS transistor P11 and thus the sensing node SO is pre-charged to the level of the source voltage Vcc.

At this time, the sensing signal SENSE having a V1 voltage at a high level is applied to the transmitting unit 120 to connect the sensing node SO to the sharing node BLCM. Accordingly, the voltages of the bit line BLe and sharing node BLCM are raised to the V1−Vt level by the sensing node SO.

In the third step (T3), the sensing signal SENSE is transited to a low level to cut off the connection between the sensing node SO and sharing node BLCM. At this time, the voltage of the bit line BLe and sharing node BLCM remains at V1−Vt where a cell to be read is a state of ‘0’ data, and is discharged to a low level where a cell to be read is a state of ‘1’ data.

Then, the pre-charge signal PRECHb at a low level is transited to a high level to cut off the source voltage Vcc from the sensing node SO.

In the fourth step (T4), the sensing signal at V2 voltage, lower than V1 voltage, is applied to the transmitting unit 120 to connect the sensing node SO to the sharing node BLCM. Accordingly, the voltage of the sensing node SO is varied depending on the sharing node BLCM. That is, in case of ‘0’ data cell, the sensing node SO remains at a high level and in case of ‘1’ data cell, the sensing node SO is discharged to a low level. The NMOS transistor N16 is turned on or off depending on the voltage of the sensing node SO.

Referring to IG. 8, the sharing node BLCM maintains the same voltage as the bit line BLe through the NMOS transistor N13. Then, the sensing signal SENSE at V2 voltage is applied to the NMOS transistor N15. At this time, when the voltage of the sharing node BLCM is less than V2−Vt, the NMOS transistor N15 is turned on. As a result, the charges on a sensing node capacitance C_{SO} are discharged to the sharing node capacitance C_{BLCM} and bit line capacitance C_{BL}. At this time, since the sharing node capacitance C_{BLCM} is much less than the bit line capacitance C_{BL}, the sum of the sharing node capacitance C_{BLCM} and bit line capacitance C_{BL} is not affected significantly by the difference of the sharing node capacitance C_{BLCM}. Therefore, in charge sharing, the lowering rate of the voltage of the sensing node SO is constant regardless of the disposition of a page buffer. This means that the sensing current of the page buffer is constant and thus the reading margin of the page buffer becomes much greater as shown in FIG. 9.

Afterwards, the reading signal READ at a high level is applied to the NMOS transistor N17 of the sensing unit 130 and turns on the NMOS transistor N17. Accordingly, when the sensing node SO is at a high level, the NMOS transistors N16 and N17 are turned on simultaneously such that the node QB becomes a low level. In contrast, when the sensing node SO is at a low level, the NMOS transistor N16 is turned off and the node QB remains in a reset state, that is, at a high level, even though the NMOS transistor N17 is turned on.

As described above in detail, when one page buffer is performing a reading operation, an adjacent page buffer performs a reading operation. At this time, the wiring lengths of the sensing nodes of the respective page buffer are the same, as shown in FIG. 5, and thus the loading time periods thereof are the same. In addition, the respective sensing node wirings of the adjacent page buffers are not disposed on the same level, but on a low level or high level, thereby avoiding interference effects between them. As a result, a drop in the sensing node can be avoided.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting.

What is claimed is:

1. A flash memory device including:
a memory cell array comprising a plurality of memory cells and a plurality of pairs of bit lines, wherein each memory cell is connected to a bit line; and
a plurality of page buffers to read the data from a memory cell selected from the plurality of memory cells, wherein each of the plurality of page buffers is connected to one of the plurality of pairs of bit lines,
wherein each of the plurality of page buffers includes:
a bit line selection unit that selects one bit line from the pair of bit lines connected to the page buffer and connects selected bit line to a sharing node;
a transmitting unit that connects the sharing node to the sensing node; and
a sensing unit that stores the data transmitted through the sensing node,
wherein the bit line selection unit is disposed on a high voltage region of a memory device, and the transmitting unit and sensing unit are disposed on a low voltage region of the device.

2. The flash memory device according to claim 1, wherein the plurality of page buffers each include sensing node wirings of the same length.

3. The flash memory device according to claim 2, wherein the sensing node wirings of adjacent page buffers are disposed on either a low level or a high level so as to not be directly adjacent to each other.

4. The flash memory device according to claim 1, wherein the bit line selection unit comprises:
a bias applying circuit to apply a bias voltage to at least one of the pair of bit lines in response to a discharge signal; and
a bit line connector that connects one of the pair of bit lines to the sharing node.

5. The flash memory device according to claim 1, wherein the transmitting unit pre-charges the voltage of the sharing node by using the voltage of the sensing node in response to a to a first sensing signal, or transmits data from the selected memory cell, which data is transmitted from the sharing node to the sensing node through a charge sharing action, in response to a second sensing signal.

6. The flash memory device according to claim 1, wherein the sensing unit comprises:
a latch for storing data;
a reset circuit for resetting the latch in response to a reset signal; and
a sensing circuit for transmitting the data from the selected memory cell to the latch.

7. A reading method for a flash memory device including a memory cell array comprising a plurality of memory cells and a plurality of pairs of bit lines and a plurality of page buffers to read the data from a memory cell selected from among the plurality of memory cells, wherein each memory cell is connected to a bit line, each of the plurality of page buffers includes a sensing node of the same lengths as the sensing nodes of the remaining page buffers, and the sensing nodes of the plurality of page buffers are disposed on either a low level or a high level so as to not be directly adjacent to each other, comprising the steps of:
connecting a pair of bit lines to which a selected memory cell is connected to a sharing node of one of the plurality of page buffers;
pre-charging the sharing node to a high level;
transmitting data from the selected memory cell from the sharing node to the sensing node; and
storing the data from the selected memory cell on the page buffer.

8. The reading method for a flash memory device according to claim 7, wherein the step of connecting a selected bit line to the sharing node includes:
cutting off a bias voltage from the selected bit line in response to a discharge signal; and
connecting the selected bit line to the sharing node in response to a bit line selection signal.

9. The reading method for a flash memory device according to claim 7, wherein the step of transmitting the data to the sensing node includes:
pre-charging the sharing node by using the sensing node voltage at a source voltage level;
changing the voltage of the sharing node and transmitting the data to the sharing node depending on the state of the selected memory cell; and
connecting the sensing node to the sharing node to change the sensing node voltage and transmitting the data to the sensing node.

10. A flash memory device comprising:
a memory cell array comprising a plurality of memory cells and a plurality of bit lines;
a plurality of bit line selection units;
a plurality of transmitting units; and
a plurality of sensing units,
wherein each of the plurality of bit lines is connected to a bit line selection unit,
each of the plurality of bit line selection units is connected to a transmitting unit by a sharing node,
each of the plurality of transmitting units is connected to a sensing unit by a sensing node, and
the sensing nodes connecting each of the plurality of transmitting units to a sensing node are all of the same length.

11. The flash memory device of claim 10, wherein adjacent sensing nodes are alternatively placed at a high level or a low level so as to not be directly adjacent to each other.

12. A flash memory device comprising:
a memory cell array;
a plurality of bit line selection units connected to the memory cell array by a plurality of bit lines; and
a plurality of page buffer units, each of the plurality of bit line selection units connected to a page buffer unit by a sharing node,
wherein each page buffer unit comprises:
a transmitting unit connected to the sharing node; and
a sensing unit connected to the transmitting unit by a sensing node,
wherein the sensing nodes of each of the plurality of page buffer units are all of the same length.

13. The flash memory device of claim 12, wherein the sensing nodes of adjacent page buffers are alternatively placed at a high level or a low level so as to not be directly adjacent to each other.

14. A flash memory device comprising:
first and second bit line selection units for selecting a bit line output from a memory cell array;
first and second sharing nodes located between the first and second bit line selection units and first and second transmitting units, respectively; and
first and second sensing nodes located between the first and second transmitting units and first and second sensing units, respectively,
wherein the first and second sensing nodes are the same length, and the first sensing node is located on a first level of the device, and the second sensing node is located on a second level of the device.
